(19) United States
(12) Patent Application Publication
(10) Pub. No.: US 2008/0248639 A1
(43) Pub. Date: Oct. 9, 2008

(54) Method for forming electrode for group III nitride based compound semiconductor and method for manufacturing p-type group III nitride based compound semiconductor

(75) Inventor: Miki Moriyama, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/078,065

(22) Filed: Mar. 26, 2008

(30) Foreign Application Priority Data
Mar. 27, 2007 (JP) 2007-082809

(51) Int. Cl. H01L 21/225

(52) U.S. Cl. 438/563; 257/E21.152; 257/E21.172

(57) ABSTRACT

An undoped GaN layer having a thickness of 3 μm is formed by MOVPE on a sapphire substrate with a buffer layer composed of aluminum nitride (AlN) therebetween. A GaN layer doped with 5×10¹⁹/cm³ of Mg and having a thickness of 100 nm is formed thereon. An ITO film having a thickness of 300 nm is formed by vacuum evaporation (EB). The wafer is kept in nitrogen at 700° C. for 5 minutes so as to reduce the resistance of the GaN layer doped with 5×10¹⁹/cm³ of Mg and having a thickness of 100 nm, so that a p-GaN layer is obtained. A FeCl₃ aqueous solution is prepared, and the ITO film is removed. In this manner, a surface of the p-GaN layer having reduced resistance is exposed. The hole concentration is 4.3×10¹⁷/cm³. The resistivity is 3.0 Ωcm.

### BACKGROUND OF THE INVENTION

1. Field of the Invention

The present invention relates to a method for manufacturing a p-type semiconductor by reducing the resistance of a group III nitride based compound semiconductor doped with an acceptor impurity. Furthermore, the present invention relates to a method for forming an electrode for the resulting p-type group III nitride based compound semiconductor. The group III nitride based compound semiconductors include semiconductors represented by AlₓGa_{y}In_{1-x-y}N (where x, y, and x+y represent independently 0 or more, and 1 or less) and semiconductors containing any element for facilitating conversion to n-type/p-type or the like. Moreover, semiconductors in which a part of compositions of the group III element and the group V element have been substituted by B, Tl; P, As, Sb, and Bi are included.

2. Description of the Related Art

Regarding the group III nitride based compound semiconductor device, a p-type semiconductor having low resistance cannot be formed merely by epitaxial growth. Therefore, a step of activating a layer doped with an acceptor impurity is necessary prior to formation of a device shape and formation of an ohmic electrode by, for example, etching. At this time, if the activation is unsatisfactory, a p-type semiconductor having high resistance results, and problems occur in that, for example, the contact resistance of the electrode increases and abnormality in light emission, e.g., non-emission, of a light-emitting device occurs.

In a well known technology for activating a layer doped with an acceptor impurity, a heat treatment is conducted in an atmosphere of nitrogen or a gas containing oxygen at a temperature within the range of 500° C. to 800° C. for a few seconds to a few tens of minutes. The purpose of this is to abstract remaining hydrogen atoms responsible for deactivating the layer doped with an acceptor impurity. Alternatively, a technology for activating a layer doped with an acceptor impurity by an application of electron beams has been known as well.

A technology for using a hydrogen absorption metal as an electrode is disclosed in Japanese Unexamined Patent Application Publication No. 08-032115 and Japanese Unexamined Patent Application Publication No. 11-354458.

It is not always easy to form a p-electrode exhibiting good ohmic properties for a p-type group III nitride based compound semiconductor having reduced resistance. Recently, it was reported that a film of metal electrode was formed after a p-InGaN film having a potential barrier lower than the potential barrier of p-GaN was formed as a contact layer.

For example, formation of a p-InGaN layer (film) as a contact layer refers to that an uppermost layer of an epitaxially grown layer is composed of the p-InGaN layer (film). However, it is well known that InGaN is easily decomposed by heat as compared with GaN. Therefore, growth of an InGaN epitaxial layer is conducted at low temperatures. Consequently, a surface of the grown InGaN layer is significantly uneven as compared with a surface of the GaN layer, and pits (holes) are noticeable. Since InGaN is easily decomposed by heat as compared with GaN, nitrogen vacancies tend to occur. Regarding the group III nitride based compound semiconductor, the nitrogen vacancy leads to a free electron and, therefore, there is a problem in that nitrogen vacancies in p-InGaN reduces the hole concentration.

### SUMMARY OF THE INVENTION

The present inventors have completed a method for obtaining a p-type group III nitride based compound semiconductor having low resistance on the basis of a quite new idea. Furthermore, a method for forming an electrode exhibiting good ohmic properties for a p-type group III nitride based compound semiconductor has been completed.

A method for forming an electrode for a group III nitride based compound semiconductor doped with an acceptor impurity according to a first aspect of the invention includes the steps of forming an oxide film composed of an oxide of an element which forms a compound with the group III nitride based compound semiconductor, the resulting compound having a band gap energy lower than the band gap energy of the group III nitride based compound semiconductor, so as to cover an exposed surface of the group III nitride based compound semiconductor doped with the acceptor impurity, reducing the resistance of the group III nitride based compound semiconductor by a heat treatment, removing the oxide film, and forming an electrode on an exposed surface of the group III nitride based compound semiconductor from which the oxide film has been removed.

In the method according to the first aspect of the invention, it is assumed that the exposed surface of the group III nitride based compound semiconductor doped with the acceptor impurity is entirely covered with the oxide film because the resistance of a portion, which is in contact with the oxide film, of the group III nitride based compound semiconductor is reduced. As a matter of course, the present invention include the case where a part of the exposed surface of the group III nitride based compound semiconductor doped with the acceptor impurity is not covered with the oxide film on the basis of a design.

The concept “an oxide of an element which forms a compound with the group III nitride based compound semiconductor, the resulting compound having a band gap energy lower than the band gap energy of the group III nitride based compound semiconductor” includes oxides to be specifically mentioned in a second aspect of the invention. For example, in the case where In substitutes for a part of Ga in a GaN layer to become InGaN, the band gap energy of InGaN is smaller than that of GaN. In this exemplary case, the element is In, and the oxide is In₂O₃, for example.

In the second aspect of the invention, the oxide film may be indium oxide, indium tin oxide, indium zinc oxide, indium oxide containing an impurity, zinc oxide containing an impurity, or titanium oxide containing an impurity.

Regarding indium tin oxide (ITO), a base material is indium oxide (In₂O₃), and tin (Sn) has substituted for about 10% or less of indium. Regarding indium zinc oxide (IZO), a base material is also indium oxide (In₂O₃), and zinc (Zn) has substituted for a ten-odd percent or less of indium. In the second aspect of the invention, in the case where an oxide film composed of IO, ITO, IZO, doped IO, doped ZnO, or doped TiO₂ is formed, it is assumed that the exposed surface of the group III nitride based compound semiconductor doped with the acceptor impurity is entirely covered with the oxide film composed of IO, ITO, IZO, doped IO, doped ZnO, or doped TiO₂ because the resistance of a portion, which is in contact with IO, ITO, IZO, doped IO, doped ZnO, or doped TiO₂, of the group III nitride based compound semiconductor doped with the acceptor impurity is reduced. As a matter of course, the present invention include the case where a part of the exposed surface of an group III nitride based compound semiconductor doped with the acceptor impurity is not covered with the oxide film composed of IO, ITO, IZO, doped IO, doped ZnO, or doped TiO₂ on the basis of a design.

In a third aspect of the invention, the acceptor impurity may be magnesium (Mg).

In a fourth aspect of the invention, the group III nitride based compound semiconductor doped with an acceptor impurity may be aluminum nitride (AlN), aluminum gallium nitride (AlGaN), or gallium nitride (GaN).

In a fifth aspect of the invention, wet etching may be used in removal of the oxide film after the heat treatment.

In a sixth aspect of the invention, the electrode may be directly formed on the group III nitride based compound semiconductor and be composed of aluminum or an alloy containing aluminum as a primary component.

In a seventh aspect of the invention, the electrode may be formed by laminating a contact electrode layer having a thickness of 5 nm or less and an aluminum layer on the group III nitride based compound semiconductor. In this case, an electrode in which alloying has been conducted by heating or the like after formation by lamination and, thereby, a lamination structure has become difficult to discriminate is included.

A method for manufacturing a p-type group III nitride based compound semiconductor by reducing the resistance of the group III nitride based compound semiconductor doped with an acceptor impurity, according to an eighth aspect of the invention, includes the steps of forming an oxide film composed of indium oxide, indium tin oxide, indium zinc oxide, or indium oxide containing an impurity so as to cover an exposed surface of the group III nitride based compound semiconductor doped with the acceptor impurity, conducting a heat treatment at 600° C. to 800° C. for 10 seconds to 30 minutes, and removing the above-described oxide film so as to obtain a p-type group III nitride based compound semiconductor having reduced resistance.

### (Hydrogen Abstraction Effect of Oxide Film)

In the present invention, by the heat treatment, an oxygen atom in the oxide film effectively abstracts hydrogen remaining in the group III nitride based compound semiconductor doped with an acceptor impurity. At this time, direct contact of the oxide film with the group III nitride based compound semiconductor doped with an acceptor impurity enhances the effect of removing hydrogen, the semiconductor serving as a layer (contact layer) on which an electrode is formed afterward. Consequently, activation of the acceptor impurity of the group III nitride based compound semiconductor doped with the acceptor impurity is facilitated and, thereby, resistance reduction of the group III nitride based compound semiconductor is facilitated. That is, a method for obtaining a p-type group III nitride based compound semiconductor having low resistance is provided. The contact resistance to an electrode formed after removal of the oxide film can be reduced by resistance reduction of the p-type group III nitride based compound semiconductor. Furthermore, when the electrode is formed and, thereby, a device is constructed, the driving voltage is reduced, so that an improvement of the device performance, in particular an increase in the device life, can be facilitated by restriction of a temperature increase.

### (Effect of Oxide Film on Prevention of Nitrogen Elimination)

In the heat treatment for reducing the resistance, the oxide film serves as a so-called cap layer and prevents elimination of nitrogen from the group III nitride based compound semiconductor doped with the acceptor impurity. Consequently, the surface of p-type group III nitride based compound semiconductor after the oxide film is removed is not roughened, and a nitrogen vacancy does not occur in the p-type group III nitride based compound semiconductor. From these points as well, when the electrode is formed and, thereby, a device is constructed, the driving voltage is reduced, so that an improvement of the device performance, in particular an increase in the device life, can be facilitated by restriction of a temperature increase.

(Effect of Doping from Oxide Film)

When an oxide film containing, for example, indium (In) is formed on an AlN, AlGaN, or GaN layer not containing In, for example, and a heat treatment is conducted, In atoms diffuse into the AlN, AlGaN, or GaN layer. Consequently, In substitutes for a part of Al or Ga in the composition of a surface layer of the AlN, AlGaN, or GaN layer, and the composition of an interface between the AlN, AlGaN, or GaN layer and the oxide film containing In becomes AlInN, AlGaInN, or GaInN. In the case where an oxide film containing indium (In) is formed on a quaternary AlGaInN layer containing In (including a ternary system not containing any one of Al and Ga) and a heat treatment is conducted, the In composition of the quaternary AlGaInN layer increases (including the case of ternary AlInN or ternary GaInN).

Since the band gap energy of the group III nitride based compound semiconductor becomes smaller as the In composition increases, the surface layer of the group III nitride based compound semiconductor becomes a thin film layer having smaller band gap energy by the formation of the oxide film containing indium (In) and the heat treatment. In this manner, the group III nitride based compound semiconductor includes the thin film layer having smaller band gap energy as a surface layer. Therefore, in the case where an electrode is formed, the contact resistance can be reduced. Consequently, in the present invention, the thin film layer having smaller band gap energy can be formed as the surface layer of the group III nitride based compound semiconductor and the contact resistance to an electrode material can be reduced by the formation of the oxide film containing indium (In) and the heat treatment.

To put this briefly, it is theoretically favorable that the oxide of “an element which forms a compound with the group III nitride based compound semiconductor, the resulting compound having a band gap energy lower than the band gap energy of the group III nitride based compound semiconductor” is used as the oxide film according to the present invention. That is, all oxides of such elements can be adopted as the oxide film according to the present invention. Examples of such elements include thallium (Tl) which belongs to the group III (group 13) similarly to indium (In) and which has a larger atomic diameter. Furthermore, titanium (Ti), zirconium (Zr), niobium (Nb), tantalum (Ta), and tungsten (W) are included, where their nitrides have electrical conductivity. Elements of the group II (elements of the group 2 or the group 12), e.g., zinc (Zn), beryllium (Be), and calcium (Ca), which can serve as acceptors in the case where the group III nitride based compound semiconductor is doped with them, are also preferable. In consideration of the removal operation to be conducted afterward, for example, ZnO or TiO₂ can be used favorably.

### BRIEF DESCRIPTION OF THE DRAWINGS

FIGS. 1A to 1D are process diagrams in Example 1.

FIG. 2 is a plan view and a sectional view showing the shapes of electrodes C and R in Example 2.

FIG. 3A is a diagram showing a V-I curve indicating the results of Example 2, and FIG. 3B is a diagram showing a V-I curve indicating the results of Comparative example 2.

FIG. 4 is a sectional view showing the configuration of a group III nitride based compound semiconductor light-emitting device according to a specific example of the present invention.

### DESCRIPTION OF THE PREFERRED EMBODIMENTS

The present invention can be applied to resistance reduction of the group III nitride based compound semiconductor having any composition and doped with any acceptor impurity and formation of any electrode for the p-type group III nitride based compound semiconductor produced by the resistance reduction. Preferably, at least a layer to become an exposed surface of the group III nitride based compound semiconductor, which is an object of the resistance reduction, is AlGaN not including indium (In). In particular, GaN is preferable. Magnesium is particularly preferable as the acceptor impurity. However, any element capable of serving as an acceptor impurity may be used.

In preferable indium tin oxide (ITO), tin has substituted for a few percent of indium. Regarding indium oxide containing an impurity (doped IO), fluorine, tellurium, titanium, antimony, zirconium, tungsten, molybdenum, zinc, and any other impurity can be used. In the use for the oxide film according to the present invention, it is favorable that the impurity added to indium oxide is an element capable of substituting for a site of indium or oxygen without significantly changing the crystal structure of indium oxide serving as a base material. The same goes for oxides of other elements. However, the crystallinity, the electrical conductivity, the light transmission property, and other properties need not be taken into consideration significantly.

For example, it is favorable that the thickness of the oxide film is specified to be 5 nm or more, and 2 μm or less. If the thickness is less than 5 nm, the hydrogen abstraction effect is poor. If the thickness is 2 μm or more, the effect becomes not commensurate with the cost. More preferably, the thickness of the oxide film is 50 nm or more, and 500 nm or less, and 100 nm or more, and 300 nm or less is further preferable.

For example, regarding the method for forming the oxide film composed of IO, ITO, IZO, doped IO, doped ZnO, or doped TiO₂, the oxide itself may be formed into a film by a vacuum evaporation method, a CVD method, a spraying method, a magnetron sputtering method, a pulsed laser deposition method, or the like depending on the compound. In addition, a method in which evaporation of an element is conducted in an oxygen atmosphere or a method in which oxidation is conducted after evaporation of the element may be employed. Alternatively, a formation method in which coating is conducted by spin coating or the like may be employed.

Preferably, the heat treatment after the oxide film is formed is conducted at 600° C. to 800° C. If the temperature exceeds 800° C., the properties of the group III nitride based compound semiconductor of a device-formation layer may deteriorate because of an undesired side reaction. If the temperature is lower than 600° C., the hydrogen abstraction effect becomes unsatisfactory or significant extension of the heating time is required. Preferably, the atmosphere gas does not include chemical species, e.g., ammonia and hydrogen, containing hydrogen as a constituent element. Preferably, the atmosphere gas is an inert gas, e.g., nitrogen. However, for example, oxygen may be included. Any pressure within the range of atmospheric pressure to a reduced pressure can be employed. Preferably, the heating time is 10 seconds to 30 minutes after a target temperature is reached. However, it is believed that the heating time of 1 to 5 minutes is satisfactory in many cases.

Incidental contamination of chemical species containing hydrogen as a constituent element into the treatment system (all contamination) is not excluded. The heat treatment for resistance reduction of the group III nitride based compound semiconductor according to the present invention refers to a heat treatment in an atmosphere in which a chemical species containing hydrogen as a constituent element is not used intentionally, and, therefore, complete exclusion of contamination is not specified.

In removal of the oxide film after the heat treatment, any etching solution capable of dissolving the compound constituting the oxide film can be used. As a matter of course, a solution which adversely affects the group III nitride based compound semiconductor or the group III nitride based compound semiconductor device to be obtained is not used. In the following examples, a FeCl₃ aqueous solution is used for removing ITO. However, any etching solution for ITO may be used.

According to the present invention, for example, an electrode of aluminum simple substance and an electrode composed of an alloy containing aluminum as a primary component can be used, while it has been previously believed that these are not suitable for the contact electrode of the p-type group III nitride based compound semiconductor. In the case where aluminum is also used for the n-electrode, simplification of the production process and cost reduction of the produced semiconductor device can be realized by conducting the evaporation steps in a single step. In the case where an aluminum electrode is formed interposing a contact electrode, it is possible that the contact electrode is specified to be a few nanometers or less, and furthermore 1 nm or less and, thereby, a highly light reflective function of aluminum is allowed to exert to the greatest extent. In the case where a lamination electrode having the same structure is also used for the n-electrode, simplification of the production process and cost reduction of the produced semiconductor device can be realized by conducting the evaporation steps of individual layers in a single step. The same goes for the case where the electrode composed of an alloy containing aluminum as a primary component is used.

A group III nitride based compound semiconductor light-emitting device can be favorably produced by employing the present invention. In this case, the light-emitting device can have any configuration. The light-emitting device may be a light-emitting diode (LED), a laser diode (LD), a photocoupler, or any other light-emitting device. Any manufacturing method can be employed as the method for manufacturing a light-emitting device.

Specifically, sapphire, spinel, Si, SiC, ZnO, MgO, a group III nitride based compound single crystal, or the like can be used as a substrate for growing a crystal. Effective methods for crystal-growing the group III nitride based compound semiconductor layer include a molecular beam vapor phase epitaxy method (MBE), a metal organic vapor phase epitaxy method (MOVPE), and a hydride vapor phase epitaxy method (HVPE).

In the case where an n-type group III nitride based compound semiconductor layer is formed, Si, Ge, Se, Te, C, or the like can be added as an n-type impurity, and Zn, Mg, Be, Ca, Sr, Ba, or the like can be added as a p-type impurity.

A light-emitting layer may have any configuration, e.g., a single layer, a single quantum well structure (SQW), and a multiple quantum well structure (MQW).

The present invention can be applied to the case where a highly reflective p-electrode is formed for a flip chip type light-emitting device. Preferably, the highly reflective electrode has good reflectivity in a green to blue wavelength region, and furthermore a near ultraviolet wavelength region. Preferably, aluminum, rhodium, platinum, or silver is used as the metal simple substance.

A part of the essence of the present invention is to reduce the resistance of the group III nitride based compound semiconductor doped with an acceptor (to convert to p-type) while the semiconductor is covered with ITO. An electrode formed on the p-type layer after ITO is removed is not limited to aluminum or other highly reflective electrodes. For example, a light transmissive electrode can also be formed. Formation of a fresh light transmissive electrode composed of ITO in this case is included in the present invention.

Alternatively, in the case where a device other than the light-emitting device, a transistor including HEMT, is formed from the group III nitride based compound semiconductor, the present invention can be applied to resistance reduction (conversion to p-type) before formation of the p-electrode.

### Example 1

A p-type group III nitride based compound semiconductor was obtained by application of the present invention, and the carrier concentration and the resistance were examined as described below.

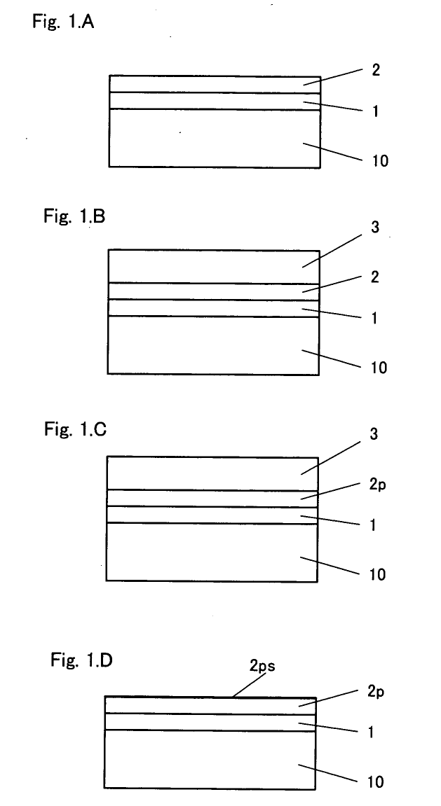

As shown in FIG. 1A, an undoped GaN layer 1 having a thickness of 3 μm was formed by MOVPE on a sapphire substrate 10 with a buffer layer composed of aluminum nitride (AlN), although not shown in the drawing, therebetween. A GaN layer 2 doped with 5×10¹⁹/cm³ of Mg and having a thickness of 100 nm was formed thereon.

As shown in FIG. 1B, an ITO film 3 having a thickness of 300 nm was formed by vacuum evaporation (EB).

The wafer was kept in nitrogen at 700° C. for 5 minutes so as to reduce the resistance of the GaN layer 2 doped with 5×10¹⁹/cm³ of Mg and having a thickness of 100 nm, so that a p-GaN layer 2p was obtained (FIG. 1C).

A FeCl₃ aqueous solution was prepared, and the ITO film 3 was removed. In this manner, a surface 2psof the p-GaN layer 2p having reduced resistance was exposed (FIG. 1D).

Thereafter, an electrode was formed, and the hole concentration and the resistivity were measured. The hole concentration was 4.3×10¹⁷/cm³. The resistivity was 3.0 Ωcm.

### Comparative Example 1

In Example 1, in the case where the ITO film 3 was not formed and a heat treatment was conducted in nitrogen at 700° C. for 5 minutes while the surface of the GaN layer 2 was exposed, the hole concentration was 7.6×10¹⁶/cm³, and the resistivity was 17.2 Ωcm. In the case where the ITO film 3 was not formed and a heat treatment was conducted in oxygen at 550° C. for 5 minutes while the surface of the GaN layer 2 was exposed, the hole concentration was 5.4×10¹⁶/cm³, and the resistivity was 21.6 Ωcm.

As described above, according to the method of the present invention, in which the ITO film 3 was formed and the heat treatment was conducted, the hole concentration was 5.7 times the hole concentration in the case where the heat treatment was conducted in nitrogen while the surface of the GaN layer 2 was exposed, and the resistivity was about one-sixth of the resistivity in that case.

### Example 2

As in Example 1, an undoped GaN layer 1 having a thickness of 3 μm and a GaN layer 2 doped with Mg and having a thickness of 100 nm were formed on a sapphire substrate 10 with a buffer layer therebetween. Covering with an ITO film 3 and a heat treatment were conducted, so that the resistance of the GaN layer 2 was reduced and a p-GaN layer 2p was obtained. Thereafter, the ITO film 3 was removed with a FeCl₃ aqueous solution.

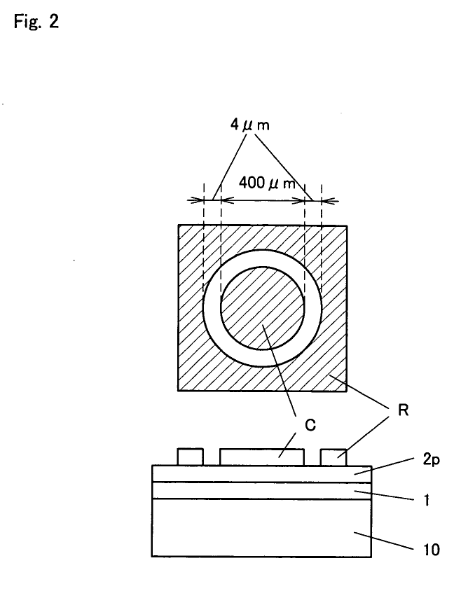

Electrodes C and R shown in FIG. 2 were formed on a surface 2psof the p-GaN layer 2p by vacuum evaporation (EB). The electrodes may be formed by sputtering.

The electrode C shown in FIG. 2 was in the shape of a circular disk having a diameter of 400 μm, and the electrode R was formed into the shape of a ring at a distance 4 μm from the electrode C.

The following four types of electrodes were formed and a TLM measurement was conducted.

1. Nickel (Ni) having a film thickness of 200 nm.
2. Aluminum (Al) having a film thickness of 300 nm.
3. A laminate composed of a lower layer formed from titanium (Ti) of 0.5 nm thickness and an upper layer formed from aluminum (Al) of 300 nm thickness.
4. A laminate composed of a lower layer formed from nickel (Ni) of 0.5 nm thickness and an upper layer formed from aluminum (Al) of 300 nm thickness.

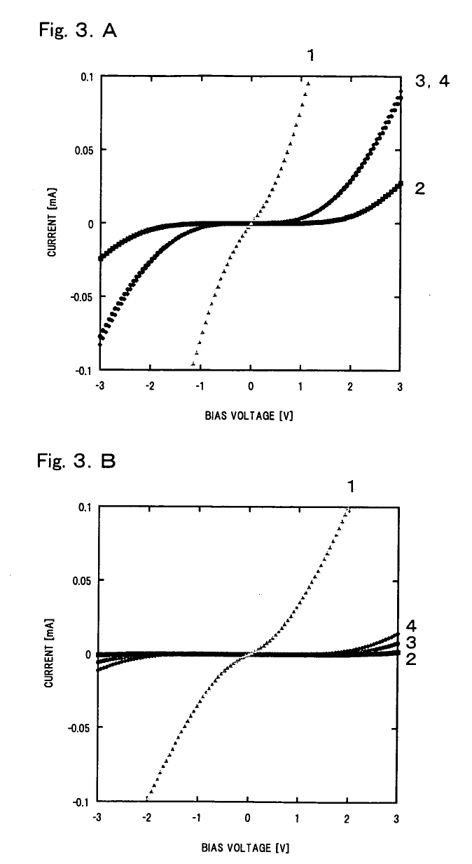

FIG. 3A shows V-I curves in the above-described four cases.

### Comparative Example 2

Regarding Comparative example 1 in which the ITO film 3 was not formed and the heating was conducted in nitrogen, four types of electrodes were formed and the TLM measurement was conducted as in Example 2. FIG. 3B shows V-I curves related to Comparative example 2.

As is clear from comparisons between FIG. 3A and FIG. 3B, regarding each of the above-described electrodes of items 1 to 4, electrical characteristics of the case where the ITO film 3 was formed and the heat treatment was conducted in Example 2 were improved significantly as compared with those in Comparative example 2 in which merely the heat treatment was conducted in nitrogen. That is, regarding the nickel (Ni) simple substance electrode, the voltage at which the current reached 0.1 mA was 2 V in Comparative example 2 shown in FIG. 3B, whereas in Example 2 shown in FIG. 3A, the voltage was 1.1 V. Regarding the aluminum (Al) simple substance electrode, when the voltage was 3 V, the current was about 0 mA in Comparative example 2 shown in FIG. 3B, whereas in Example 2 shown in FIG. 3A, a current of 0.025 mA passed. Regarding the case where the aluminum electrode was formed interposing the thin film contact electrode of titanium or nickel, when the voltage was 3 V, the current was less than 0.02 mA in Comparative example 2 shown in FIG. 3B, whereas in Example 2 shown in FIG. 3A, a current exceeding 0.08 mA passed.

As is shown from comparisons between Example 2 (FIG. 3A) and Comparative example 2 (FIG. 3B), for example, an aluminum simple substance cannot be used as an electrode in the case where the resistance of the group III nitride based compound semiconductor doped with an acceptor impurity is merely reduced in nitrogen, but the aluminum simple substance can be used as an electrode in the case where covering with the oxide film containing indium oxide as a base material, a heat treatment, and removal by chemical etching are conducted according to the present invention.

This indicates that not only the p-GaN layer 2p had a satisfactorily reduced resistance, but also the contact resistance to the metal electrodes C and R was reduced significantly. The factors thereof are believed to be that activation of Mg serving as an acceptor impurity of the p-GaN layer 2p was facilitated so as to increase the carrier concentration and, in addition, a p-InGaN thin film was formed as the surface 2psof the p-GaN layer 2p by movement of In from the ITO layer 3 to the p-GaN layer 2p according to the present invention. That is, it is believed that the energy barrier between the p-InGaN thin film as the surface 2psof the p-GaN layer 2p and the metal electrodes C and R is reduced and, thereby, the contact resistance is reduced, so as to cause the difference between Example 2 and Comparative example 2.

It was verified from the present example that the thin film layer having low band gap energy was able to be formed as the surface layer of the group III nitride based compound semiconductor and the contact resistance to the electrode material was able to be reduced by formation of the oxide film containing indium (In) and the heat treatment. Consequently, the oxide film is required to be formed from an oxide containing at least indium, and, for example, indium oxide (IO) can be used as an oxide film. Likewise, IZO and other IO based compounds, in which a base material is IO and ten-odd percent or less of 1n elements have been substituted with other metal elements or the like, and IO based oxides, e.g., FIO, doped with fluorine can be used.

Furthermore, it is understood that similar results can be obtained by using an oxide of the “element which forms a compound with the group III nitride based compound semiconductor, the resulting compound having a band gap energy lower than the band gap energy of the group III nitride based compound semiconductor”. Examples of such elements include thallium (Tl) having an atomic diameter larger than that of indium (In); and titanium (Ti), zirconium (Zr), niobium (Nb), tantalum (Ta), and tungsten (W), nitrides of which have electrical conductivity. Elements of the group II (elements of the group 2 and the group 12), for example, zinc (Zn), beryllium (Be), and calcium (Ca), which can serve as acceptors when the group III nitride based compound semiconductor is doped with them, are also preferable. In consideration of the removal operation to be conducted afterward, for example, ZnO or TiO₂ can be used favorably.

### Example 3

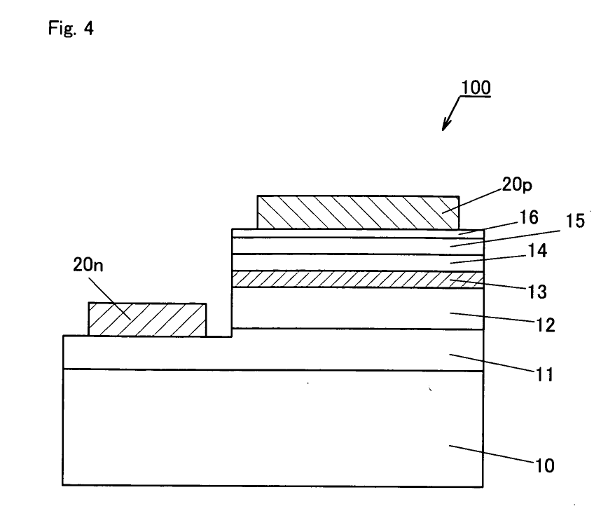

FIG. 4 is a sectional view showing the configuration of a group III nitride based compound semiconductor light-emitting device 100 according to the present example. The group III nitride based compound semiconductor light-emitting device 100 is produced by forming a buffer layer composed of aluminum nitride (AlN), although not shown in the drawing, on a sapphire substrate 10 and, thereafter, laminating an n-type GaN layer 11 doped with Si, an n-type AlGaN clad layer 12 doped with Si, a light-emitting layer 13 having a GaN/InGaN multiple quantum well structure, a p-type AlGaN clad layer 14 doped with Mg, a p-type GaN layer 15 doped with Mg, and p⁺-type GaN layer 16 sequentially by MOCVD (MOVPE).

A p-electrode 20p is disposed on the p-type GaN layer 16, and an n-electrode 20n is disposed on the n-type GaN layer 11. The p-electrode 20p and the n-electrode 20n are formed from an aluminum single layer or a lamination structure composed of a contact electrode layer and an aluminum layer. The group III nitride based compound semiconductor light-emitting device 100 is a flip chip type LED, wherein the p-electrode 20p and the n-electrode 20n are light reflective electrode layers and the light is taken out from the sapphire substrate 10 side.

A method for manufacturing this light-emitting device 100 will be described below. The gases to be used are ammonia (NH₃), a carrier gas (H₂, N₂), trimethylgallium (TMG), trimethylaluminum (TMA), trimethylindium (TMI), silane (SiH₄), and cyclopentadienyl magnesium (Cp₂Mg).

A single crystal sapphire substrate 10, in which an a-face cleaned with organic cleaning and a heat treatment was assumed to be a principal surface, was mounted on a susceptor placed in a reaction chamber of a MOCVD apparatus. The sapphire substrate 10 was baked at a temperature of 1,100° C. for about 30 minutes while H₂ was passed into the reaction chamber at normal pressure at a flow rate of 2 L/min (L represents liter).

An AlN buffer layer having a thickness of about 25 nm was formed by lowering the temperature to 400° C. and supplying 20 L/min of H₂, 10 L/min of NH₃, and 1.8×10⁻⁵ mol/min of TMA for about 1 minute.

An n-type GaN layer 11 having a film thickness of about 4.0 μm, an electron concentration of 2×10¹⁸/cm³, and a silicon concentration of 4×10¹⁸/cm³ was formed by keeping the temperature of the sapphire substrate 10 at 1,150° C. and supplying 20 L/min of H₂, 10 L/min of NH₃, 1.7×10⁻⁴ mol/min of TMG, and 20×10⁻⁸ mol/min of silane diluted to 0.86 ppm with a H₂ gas for 40 minutes.

An n-clad layer 12 composed of Al_{0.08}Ga_{0.92}N having a film thickness of about 0.5 μm, an electron concentration of 1×10¹⁸/cm³, and a silicon concentration of 2×10¹⁸/cm³ was formed by keeping the temperature of the sapphire substrate 10 at 1,150° C. and supplying 10 L/min of N₂ or H₂, 10 L/min of NH₃, 1.12×10⁻⁴ mol/min of TMG, 0.47×10⁻⁴ mol/min of TMA, and 5×10⁻⁹ mol/min of silane diluted to 0.86 ppm with a H₂ gas for 60 minutes.

After the above-described n-clad layer 12 was formed, a barrier layer composed of GaN having a film thickness of about 35 Å was formed continuously by supplying 20 L/min of N₂ or H₂, 10 L/min of NH₃, and 2.0×10⁻⁴ mol/min of TMG for 1 minute. Subsequently, a well layer composed of In_{0.20}Ga_{0.80}N having a film thickness of about 35 Å was formed by keeping the amounts of supply of N₂ or H₂ and NH₃ at constant and supplying 7.2×10⁻⁵ mol/min of TMG and 0.19×10⁻⁴ mol/min of TMI for 1 minute. Furthermore, five cycles of the barrier layer and the well layer were formed under the same condition, and a barrier layer composed of GaN was formed thereon. In this manner, a light-emitting layer 13 having a five-cycle MQW structure was formed.

A p-clad layer 14 composed of p-type Al_{0.15}Ga_{0.85}N, doped with magnesium (Mg), and having a film thickness of about 50 nm and a magnesium (Mg) concentration of 5×10¹⁹/cm³ was formed by keeping the temperature of the sapphire substrate 10 at 1,100° C. and supplying 10 L/min of N₂ or H₂, 10 L/min of NH₃, 1.0×10⁻⁴ mol/min of TMG, 1.0×10⁻⁴ mol/min of TMA, and 2×10⁻⁵ mol/min of Cp₂Mg for 3 minutes.

A p-type GaN layer 15 doped with magnesium (Mg) and having a film thickness of about 100 nm and a magnesium (Mg) concentration of 5×10¹⁹/cm³ was formed by keeping the temperature of the sapphire substrate 10 at 1,100° C. and supplying 20 L/min of N₂ or H₂, 10 L/min of NH₃, 1.12×10⁻⁴ mol/min of TMG, and 2×10⁻⁵ mol/min of Cp₂Mg for 30 seconds. Furthermore, a p⁺-type GaN layer 16 doped with magnesium (Mg) and having a film thickness of about 10 nm and a magnesium (Mg) concentration of 1×10²⁰/cm³ was formed on the p-type GaN layer 15.

An ITO film having a thickness of 300 nm was formed by vacuum evaporation (EB) at a substrate temperature of 300° C. on the p⁺-type GaN layer 16 doped with magnesium (Mg). A heat treatment was conducted in nitrogen at 700° C. for 5 minutes so as to reduce the resistance of the p-type GaN layer 15 and the p⁺-type GaN layer 16. Thereafter, the Ito film was removed with a FeCl₃ aqueous solution so as to expose the p⁺-type GaN layer 16.

An etching mask composed of a resist was formed on the p⁺-type GaN layer 16, the mask in a predetermined region was removed, a part of portions, which are not covered with the mask, of the p⁺-type GaN layer 16, the p-type GaN layer 15, the p-clad layer 14, the light-emitting layer 13, the n-clad layer 12, and the n-type GaN layer 11 were etched by reactive ion etching with a gas containing chlorine so as to expose the surface of the n-type GaN layer 11. After the resist mask was removed, an n-electrode 20n for the n-type GaN layer 11 and a p-electrode 20p for the p⁺-type GaN layer 16 were formed by the following procedure.

A photoresist was applied, a window was formed in a predetermined region by photolithography and, thereafter, the n-electrode 20n for the n-type GaN layer 11 and the p-electrode 20p for the p⁺-type GaN layer 16 were formed by evaporation in a high vacuum of the order of 10⁻⁶ Torr or lower. That is, the electrode configuration of the n-electrode 20n and the p-electrode 20p were the same in the present example.

The photoresist was removed by lift-off, and the n-electrode 20n and the p-electrode 20p were formed into the desired shapes.

The electrode configurations of the n-electrode 20n and the p-electrode 20p were the following four types.

1. Aluminum (Al) of 300 nm thickness.
2. A lower layer was titanium (Ti) of 0.5 nm thickness and an upper layer was aluminum (Al) of 300 nm thickness.
3. A lower layer was nickel (Ni) of 0.5 nm thickness and an upper layer was aluminum (Al) of 300 nm thickness.
4. A lower layer was vanadium (V) of 17.5 nm thickness and an upper layer was aluminum (Al) of 300 nm thickness.

Group III nitride based compound semiconductor light-emitting devices 100, as shown in FIG. 4, having such electrodes were formed. Regarding each of them, the driving voltage Vf required for making the current 20 mA and the light output at that time were measured with a photodetector disposed on the sapphire surface side of the device. The results are shown in Table 1.

In table 1, the case where the ITO film was removed, cleaning with a hydrofluoric acid buffer solution (BHF) was conducted and, thereafter, the electrode was formed and the case where the electrode was formed without conducting BHF cleaning are described together. For purposes of comparison, the case where an ITO film was not formed, a heat treatment was conducted in nitrogen at 700° C. for 5 minutes while the p⁺-type GaN layer 16 doped with magnesium (Mg) was exposed and, thereafter, the electrode was formed (Comparative example 3) is also described.

TABLE 1

| | | | | | ITO formation, | |
|---|---|---|---|---|---|---|
| | Heating | | ITO formation, | | heating, | |
| | in nitrogen | | heating, and | | ITO removal, and | |
| | (Comparative | | ITO removal | | BHF cleaning | |
| | example) | | (Example 3) | | (Example 3) | |
| | | Light | | Light | | Light |
| | | output | | output | | output |
| | Vf (V) | (μW) | Vf (V) | (μW) | Vf (V) | (μW) |
| Al | 1.69 | 0 | 7.27 | 408 | 6.52 | 358 |
| Ti/Al | 6.45 | 30 | 5.65 | 401 | 4.98 | 355 |
| Ni/Al | 6.74 | 117 | 5.22 | 351 | 4.39 | 311 |
| V/A1 | 6.48 | 53 | 4.93 | 225 | 4.38 | 199 |

As is clear from Table 1, in the case where the electrode was formed by conducting the heat treatment in nitrogen at 700° C. for 5 minutes without forming an ITO film while the p⁺-type GaN layer 16 doped with magnesium (Mg) was exposed (Comparative example 3), light emission was not observed regarding the aluminum (Al) simple substance electrode. In the case where the contact electrode was interposed, the driving voltage Vf exceeded 6 V, and the light output was reduced to 30 to 117 μW.

On the other hand, according to the present invention, in the case where the contact electrode was interposed, the driving voltage Vf was less than 5 V when the electrode was formed after the BHF cleaning was conducted and, therefore, was better than the driving voltage Vf when the electrode was formed without BHF cleaning. Furthermore, regarding the aluminum (Al) simple substance electrode not interposing the contact electrode, good light emission was obtained. That is, it is shown that according to the present invention, the aluminum (Al) simple substance electrode or the aluminum (Al) electrode with interposition of the contact electrode can be used as a highly reflective electrode and a p-electrode of the group III nitride based compound semiconductor light-emitting device, while this has been believed to be unfavorable.

As is clear from the results shown in Table 1, the light output increased by 20% and, therefore, was significantly improved in spite of the increase in the driving voltage was 0.4 V at the maximum as compared with those in the case where the resistance reduction of the simply exposed p-layer was conducted by the heat treatment in nitrogen and a rhodium electrode was formed.

In the present example, the heat treatment after formation of the electrode (annealing or alloying) can be conducted at 200° C. or higher, and 600° C. or lower.

### Example 4

In the present example, both the n-electrode 20n and the p-electrode 20p in the group III nitride based compound semiconductor light-emitting device 100 of Example 3 were specified to be a nickel (Ni) simple substance electrode having a film thickness of 200 nm, and the state of light emission at the driving voltage Vf was examined. The nickel (Ni) simple substance electrode was formed by a sputtering method.

For purposes of comparison, treatments before and after the formation of the nickel electrode were conducted as described below.

Treatment before nickel electrode formation (Pretreatment in Table 2, where cleaning with BHF was conducted for 5 minutes just before the formation of nickel (Ni) simple substance electrode by sputtering in all the following items 1 to 4.):

1. Heat treatment or the like was not conducted.
2. Heat treatment in nitrogen at 700° C. for 5 minutes.
3. Heat treatment in dry air at 700° C. for 5 minutes.
4. Formation of ITO film, heat treatment in nitrogen at 700° C. for 5 minutes and, thereafter, removal of ITO film (the present invention).

Treatment after nickel electrode formation (Aftertreatment in Table 2):

1. Heat treatment or the like was not conducted.
2. Heat treatment in nitrogen at 400° C. for 5 minutes.
3. Heat treatment in dry air at 400° C. for 5 minutes.

The results of these 12 cases are shown in Table 2. Values of Vf (unit is V) and areas of light emission region of the electrode region are shown.

TABLE 2

| | | Pretreatment | | | |
|---|---|---|---|---|---|
| | | | | | ITO |
| | | No heat | Heating in | Heating | formation |
| | | treatment | nitrogen | in air | (Example 4) |
| After- | No heat | 5.2 V, | 5.1 V, | 3.8 V, | 3.3 V, |
| treatment | treatment | only | only | full- | full- |
| | | periphery | periphery | surface | surface |
| | | of | of | light | light |
| | | electrode | electrode | emission | emission |
| | Heating | 6.0 V, | 5.3 V, | 3.6 V, | 3.3 V, |
| | in | spot-like | full- | full- | full- |
| | nitrogen | light | surface | surface | surface |
| | | emission | light | light | light |
| | | | emission | emission | emission |
| | Heating | 3.9 V, | 4.0 V, | 3.7 V, | 3.4 V, |
| | in air | only | only | full- | full- |
| | | periphery | periphery | surface | surface |
| | | of | of | light | light |
| | | electrode | electrode | emission | emission |

The following are clear from the results shown in Table 2.

According to the present invention (in the table, Pretreatment is “ITO formation”), light emission occurred in a full-surface region of the nickel electrode even when an aftertreatment (heat treatment after electrode formation) was not conducted. In addition, the driving voltage was 3.3 V and, therefore, was quite low, so that a good light-emitting device was produced.

On the other hand, in the case where an ITO film was not formed and the pretreatment was heating in dry air (in the table, “Heating in air”), that is, oxygen was contained, light emission occurred in a full-surface region of the nickel electrode even when an aftertreatment (heat treatment after electrode formation) was not conducted, as in the present invention. However, the driving voltage Vf was 3.6 V or more and, therefore, was inferior to that in the present invention.

In the case where an ITO film was not formed and the pretreatment was heating in nitrogen, the driving voltage Vf was about 5 V and, therefore, was high or light emission occurred only in a periphery region of the nickel electrode.

In the case where an ITO film was not formed, nor was a pretreatment conducted (in the table, “No heat treatment”), full-surface light emission did not occur. In the case where heating in an atmosphere containing oxygen was not conducted in the aftertreatment, the driving voltage was 5 V or more and, therefore, was high.

That is, it is clear from the results shown in Table 2 that according to the method of the present invention in which the ITO film was formed, the heat treatment was conducted and, thereafter, the ITO film was removed, the resistance of the group III nitride based compound semiconductor doped with an acceptor impurity was able to be reduced and, in addition, a heat treatment after the formation of the p-electrode (aftertreatment) was able to be omitted or conducted at lower temperatures than ever.

In summary, according to the method in which an ITO film is formed, a heat treatment is conducted and, thereafter, the ITO film is removed as in each of the above-described examples, the resistance of a group III nitride based compound semiconductor doped with an acceptor impurity can be reduced and, in addition, the contact resistance can be reduced and the ohmic properties can be improved even when a heat treatment after formation of a p-electrode (aftertreatment) is omitted. Furthermore, since the dependence of an electrode for a p-layer on a metal or other materials is reduced (the range of choice of the electrode material increases), the p-electrode and the n-electrode can have the same electrode configuration. Consequently, inexpensive aluminum can be employed for thick film portions of the p-electrode and the n-electrode of the group III nitride based compound semiconductor light-emitting device and highly reflective electrodes can be produced. That is, an inexpensive, flip chip type group III nitride based compound semiconductor light-emitting device having an improved efficiency of taking out of light can be obtained.

As a matter of course, the above-described effects can be obtained by applying the present invention to formation of light-transmissive electrodes and formation of electrodes of transistors and other semiconductor devices.

The substrate may be heated in formation of the ITO film. The case where resistance reduction of the layer doped with an acceptor (conversion to p-type) is conducted substantially in the formation of the ITO film is also included in the present invention.

As described above, it is understood that similar results can be obtained by substituting the indium tin oxide (ITO) film in each example with an oxide film containing at least indium, for example, an oxide film which contains indium oxide as the base material and which is doped with an impurity. Furthermore, it is understood that similar results can be obtained by using the “element which forms a compound with the group III nitride based compound semiconductor, the resulting compound having a band gap energy lower than the band gap energy of the group III nitride based compound semiconductor”. Examples of such elements include thallium (Tl) having an atomic diameter larger than that of indium (In); and titanium (Ti), zirconium (Zr), niobium (Nb), tantalum (Ta), and tungsten (W), nitrides of which have electrical conductivity. Elements of the group II (elements of the group 2 and the group 12), for example, zinc (Zn), beryllium (Be), and calcium (Ca), which can serve as acceptors when the group III nitride based compound semiconductor is doped with them, are also preferable.

In the above-described examples, the light-emitting layer 13 of the light-emitting device 100 has a MQW structure. However, SQW, a single layer composed of In_{0.2}Ga_{0.8}N or the like, or any other mixed crystal of quaternary or ternary AlInGaN may be employed. Although Mg is used as the p-type impurity, elements of the group II (elements of the group 2 and the group 12), for example, beryllium (Be) and zinc (Zn), may be used.

### INDUSTRIAL APPLICABILITY

The present invention is particularly effective as a method for forming a light reflective positive electrode of a flip chip type group III nitride based compound semiconductor light-emitting device.

What is claimed is:

1. A method for forming an electrode for a group III nitride based compound semiconductor, which is doped with an acceptor impurity, the method comprising the steps of:
forming an oxide film composed of an oxide of an element which forms a compound with the group III nitride based compound semiconductor, the resulting compound having a band gap energy lower than the band gap energy of the group III nitride based compound semiconductor, so as to cover an exposed surface of the group III nitride based compound semiconductor doped with the acceptor impurity;
reducing the resistance of the group III nitride based compound semiconductor by a heat treatment;
removing the oxide film; and
forming an electrode on an exposed surface of the group III nitride based compound semiconductor from which the oxide film has been removed.

2. The method for forming an electrode for a group III nitride based compound semiconductor according to claim 1, wherein the oxide film comprises indium oxide, indium tin oxide, indium zinc oxide, indium oxide containing an impurity, zinc oxide containing an impurity, or titanium oxide containing an impurity.

3. The method for forming an electrode for a group III nitride based compound semiconductor according to claim 1, wherein the acceptor impurity comprises magnesium (Mg).

4. The method for forming an electrode for a group III nitride based compound semiconductor according to claim 2, wherein the acceptor impurity comprises magnesium (Mg).

5. The method for forming an electrode for a group III nitride based compound semiconductor according to claim 1, wherein the group III nitride based compound semiconductor doped with an acceptor impurity comprises aluminum nitride, aluminum gallium nitride, or gallium nitride.

6. The method for forming an electrode for a group III nitride based compound semiconductor according to claim 2, wherein the group III nitride based compound semiconductor doped with an acceptor impurity comprises aluminum nitride, aluminum gallium nitride, or gallium nitride.

7. The method for forming an electrode for a group III nitride based compound semiconductor according to claim 3, wherein the group III nitride based compound semiconductor doped with an acceptor impurity comprises aluminum nitride, aluminum gallium nitride, or gallium nitride.

8. The method for forming an electrode for a group III nitride based compound semiconductor according to claim 4, wherein the group III nitride based compound semiconductor doped with an acceptor impurity comprises aluminum nitride, aluminum gallium nitride, or gallium nitride.

9. The method for forming an electrode for a group III nitride based compound semiconductor according to claim 1, wherein wet etching is used in removal of the oxide film after the heat treatment.

10. The method for forming an electrode for a group III nitride based compound semiconductor according to claim 1, wherein the electrode is directly formed on the group III nitride based compound semiconductor and is composed of aluminum or an alloy containing aluminum as a primary component.

11. The method for forming an electrode for a group III nitride based compound semiconductor according to claim 2, wherein the electrode is directly formed on the group III nitride based compound semiconductor and is composed of aluminum or an alloy containing aluminum as a primary component.

12. The method for forming an electrode for a group III nitride based compound semiconductor according to claim 5, wherein the electrode is directly formed on the group III nitride based compound semiconductor and is composed of aluminum or an alloy containing aluminum as a primary component.

13. The method for forming an electrode for a group III nitride based compound semiconductor according to claim 6, wherein the electrode is directly formed on the group III nitride based compound semiconductor and is composed of aluminum or an alloy containing aluminum as a primary component.

14. The method for forming an electrode for a group III nitride based compound semiconductor according to claim 1, wherein the electrode is formed by laminating a contact electrode layer having a thickness of 5 nm or less and an aluminum layer on the group III nitride based compound semiconductor.

15. The method for forming an electrode for a group III nitride based compound semiconductor according to claim 2, wherein the electrode is formed by laminating a contact electrode layer having a thickness of 5 nm or less and an aluminum layer on the group III nitride based compound semiconductor.

16. The method for forming an electrode for a group III nitride based compound semiconductor according to claim 5, wherein the electrode is formed by laminating a contact electrode layer having a thickness of 5 nm or less and an aluminum layer on the group III nitride based compound semiconductor.

17. The method for forming an electrode for a group III nitride based compound semiconductor according to claim 6, wherein the electrode is formed by laminating a contact electrode layer having a thickness of 5 nm or less and an aluminum layer on the group III nitride based compound semiconductor.

18. A method for manufacturing a p-type group III nitride based compound semiconductor by reducing the resistance of the group III nitride based compound semiconductor doped with an acceptor impurity, the method comprising the steps of:
forming an oxide film composed of indium oxide, indium tin oxide, indium zinc oxide, or indium oxide containing an impurity so as to cover an exposed surface of the group III nitride based compound semiconductor doped with the acceptor impurity;
conducting a heat treatment at 600° C. to 800° C. for 10 seconds to 30 minutes; and
removing the above-described oxide film so as to obtain a p-type group III nitride based compound semiconductor having reduced resistance.
